(19) United States
(12) Patent Application Publication
(10) Pub. No.: US 2008/0102296 A1
(43) Pub. Date: May 1, 2008

(54) Erosion resistant coatings and methods of making

(76) Inventors: Farshad Ghasripoor, Scotia, NY (US); Norman Arnold Turnquist, Sloansville, NY (US); Kripa Kiran Varanasi, Clifton Park, NY (US); Reed Roeder Corderman, Niskayuna, NY (US); Sean Douglas Feeny, Malta, NY (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 11/588,146

(22) Filed: Oct. 26, 2006

(51) Int. Cl. C23C 16/00; B32B 15/04; B32B 9/00; H01T 14/00; B32B 19/00

(52) U.S. Cl. 428/469; 428/701; 428/702; 427/580; 427/248.1

(57) ABSTRACT

A coated turbine engine component includes a turbine engine component and an erosion resistant coating disposed on at least a portion of a surface of the turbine engine component using electron beam physical vapor deposition or ion plasma cathodic arc deposition.

### BACKGROUND OF THE INVENTION

The present disclosure relates to coating compositions and coating methods, and more particularly to erosion resistant coating compositions and coating methods.

Metal components are used in a wide variety of industrial applications, under a diverse set of operating conditions. In many cases, the components are provided with coatings, which impart various characteristics, such as corrosion resistance, heat resistance, oxidation resistance, and erosion resistance. As an example, erosion-resistant coatings are frequently used on the first stages of high pressure and intermediate pressure steam turbines that are particularly prone to solid particle erosion. In addition, erosion-resistant coatings are frequently used on compressor sections of gas turbines and jet engines that are prone to sand or other airborne solid particle erosion as well as corrosion.

Erosion of these components generally occurs by impingement of solid particles (e.g., sand in the air or boiler exfoliants in the steam) of, for example, SiO₂, Al₂O₃, Fe₂O₃, MgO, CaO, clays, volcanic ash, and the like that are carried by fluid media (i.e., air, steam, or water). Existing base materials for turbine components such as, but not limited to, martensitic stainless steels do not have adequate erosion or corrosion resistance under these conditions. The severe erosion that can result may damage the turbine components, thereby contributing to frequent maintenance related shutdowns, loss of operating efficiencies, and the need to replace various components on a regular basis.

In order to avoid or mitigate erosion problems, some power stations are configured to shut down when the solid particle content reaches a certain level to prevent further erosion. In addition to shutting down the power stations, various anti-erosion coatings have been developed to mitigate erosion. Such coatings include ceramic coatings of alumina, titania, chromia, and the like, that are frequently deposited by thermal spray techniques, such as air plasma spray (APS) and high velocity oxy-fuel (HVOF). These processes produce as-deposited coatings with rough surface textures and limited hardness, which can have adverse affects on the performance of the turbine. In addition, these processes can produce coatings that can adversely affect the high cycle fatigue strength of the substrate or base material. Finally, the coatings produced by these processes often require modification to the turbine airfoil to compensate for the thickness of the coatings.

Recent efforts to decrease the surface roughness of the erosion resistant coatings, so as to make the steam turbine component more aerodynamically efficient, include machining or polishing the as-deposited coating to a specific surface roughness. Unfortunately, these are expensive and time consuming processes. Consequently, many applications forego this type of machining or polishing.

Accordingly, there remains a need in the art for methods of producing coatings for turbine engine components with a decreased surface roughness, an increased hardness, a minimal or no decrease in high cycle fatigue strength, and/or a minimal effect on the airfoil area and surface profile. It would be particularly advantageous if the as-deposited coatings exhibit decreased surface roughness and did not require a post-deposition machining or polishing step to achieve the decreased surface roughness.

### BRIEF DESCRIPTION OF THE INVENTION

A coated turbine engine component includes a turbine engine component and an erosion resistant coating disposed on at least a portion of a surface of the turbine engine component using electron beam physical vapor deposition or ion plasma cathodic arc deposition.

In another embodiment, the coated turbine engine component includes a turbine engine component and a multilayer erosion resistant coating having a roughness average of less than or equal to about 75 microinches disposed on at least a portion of a surface of the turbine engine component.

A method includes disposing an erosion resistant coating on at least a portion of a surface of a turbine engine component by electron beam physical vapor deposition or ion plasma cathodic arc deposition.

Another method includes disposing a multilayer erosion resistant coating having a roughness average of less than or equal to about 75 microinches on at least a portion of a surface of a turbine engine component by electron beam physical vapor deposition or ion plasma cathodic arc deposition.

The above described and other features are exemplified by the following figures and detailed description.

### BRIEF DESCRIPTION OF THE DRAWINGS

Referring now to the figures, which are exemplary embodiments and wherein like elements are numbered alike:

FIG. 1 is a cross-sectional schematic illustration of a portion of an erosion resistant coating on a metal component; and

FIG. 2 is a cross-sectional schematic illustration of a portion of a turbine engine with various components having an erosion resistant coating disposed thereon.

### DETAILED DESCRIPTION OF THE INVENTION

Coating compositions and coating methods that provide erosion resistance to metal turbine engine components are disclosed herein. The methods are generally based on the electron beam-physical vapor deposition (EB-PVD) or ion plasma cathodic arc deposition of a coating on a smooth turbine engine component substrate. The methods result in coatings with decreased surface roughness relative to existing coatings. Advantageously, the as-deposited coatings do not require a post-deposition machining or polishing step to achieve the decreased surface roughness. Furthermore, the coatings provide increased dimensional stability to the coated surface during operation of the turbine. For example, the coated turbine engine component has a high cycle fatigue (HCF) strength that is greater than or equal to that of the turbine engine component without the erosion resistant coating disposed thereon. Accordingly, adverse effects, such as decreased turbine efficiency and power output, which are observed in coatings having increased surface roughness, can be reduced. These features ultimately result in increased component and turbine engine lifetimes.

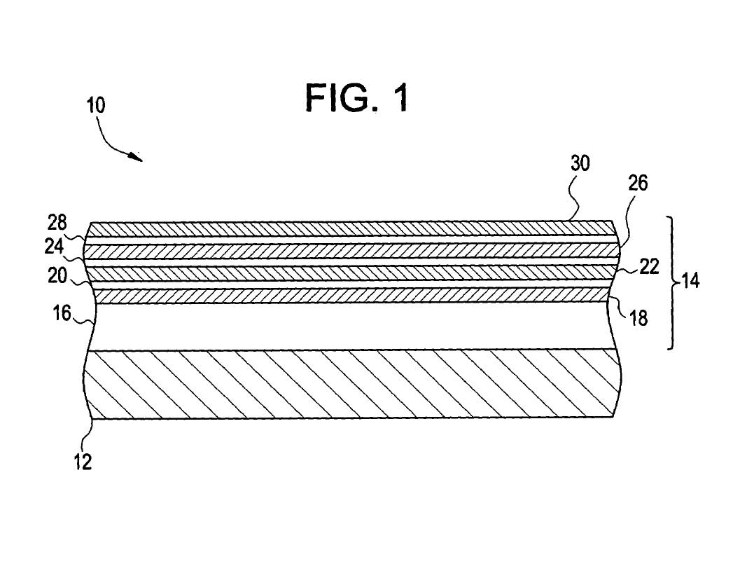

Referring now to FIG. 1, a portion of a coated article, generally designated 10, is illustrated. The portion of the coated article 10 generally includes a substrate 12 and an erosion resistant coating 14 disposed on at least a portion of a surface of the substrate 12.

The substrate 12 onto which the erosion resistant coating 14 is disposed may be any metal, metallic alloy, ceramic (e.g., oxide, nitride, carbide, and the like), or a combination comprising at least one of the foregoing (e.g., a metal/alloy-polymer composite). It is important to note that the composition and the microstructure of the substrate 12 can affect the performance of erosion resistant coating 14. In an exemplary embodiment, the substrate 12 is a turbine engine component. The form of the turbine engine component can vary among a shroud, bucket or blade, nozzle or vane, diaphragm component, seal component, valve stem, nozzle box, nozzle plate, or the like. The terms “blade” and “bucket” can be used interchangeably; generally a blade is a rotating airfoil of an aircraft turbine engine, and a bucket is a rotating airfoil of a land-based power generation turbine engine. Also the term “nozzle”, which generally refers to a stationary vane in a steam or gas turbine, can be used interchangeably with the term “vane”.

The turbine engine component generally comprises a steel and/or a superalloy. Superalloys are metallic alloys that can be used at high temperatures, often in excess of about 0.7 of the absolute melting temperature. Any Fe—, Co—, or Ni— based superalloy composition may be used to form the structural component. The most common solutes in Fe—, Co—, or Ni-based superalloys are aluminum and/or titanium. Generally, the aluminum and/or titanium concentrations are low (e.g., less than or equal to about 15 weight percent (wt %) each). Other optional components of Fe—, Co—, or Ni-based superalloys include chromium, molybdenum, cobalt (in Fe— or Ni-based superalloys), tungsten, nickel (in Fe— or Co-based superalloys), rhenium, iron (in Co— or Ni-based superalloys), tantalum, vanadium, hafnium, columbium, ruthenium, zirconium, boron, yttrium, and carbon, each of which may independently be present in an amount of less than or equal to about 15 wt %.

The specific erosion resistant coating 14 composition is chosen to provide erosion resistance to a turbine engine component that is prone to solid particle erosion. The erosion resistant coating 14 can comprise a ceramic material. Suitable ceramic compositions include metal oxides such as Al₂O₃, Cr₂O₃, Y₂O₃, ZrO₂, CeO₂, TiO₂, Ta₂O₅, TaO₂, and the like; metal carbides such as Cr₃C₂, WC, TiC, ZrC, B₄C, and the like; diamond, diamond-like carbon; metal nitrides such as BN, TiN, ZrN, HfN, CrN, Si₃N₄, AlN, TiAlN, TiAlCrN, TiCrN, TiZrN, and the like; metal borides such as TiB₂, ZrB₂, Cr₃B₂, W₂B₂, and the like; and combinations comprising at least one of the foregoing compositions (e.g., TiCN, CrBN, TiBN, and the like). Alternatively, the erosion resistant coating 14 can comprise a ceramic-metal composite (cermet). Suitable cermets include WC/Co, WC/CoCr, WC/Ni, TiC/Ni, TiC/Fe, Ni(Cr)/Cr₃C₂, TaC/Ni, and combinations comprising at least one of the foregoing. Still other embodiments of the erosion resistant coating 14 include combinations comprising at least one of the ceramics or cermets (e.g., a metal or alloy matrix comprising one of the foregoing).

In an exemplary embodiment, the erosion resistant coating 14 is a multilayer coating, as shown in FIG. 1. Within the multilayer erosion resistant coating 14, the composition of each layer may be chosen to provide an additional desired property such as corrosion resistance, heat resistance, ductility, fouling resistance (e.g., resistance to accumulation of deposits), hardness, fracture toughness, or a combination comprising at least one of the foregoing properties.

For example, the erosion resistant coating 14 can have a cross-sectional or Vickers hardness (Hᵥ) of up to about 5000 kilograms per square millimeter (kg/mm²). Within this range, the hardness of the erosion resistant coating 14 is greater than or equal to about 500 kg/mm². In one embodiment, the hardness of the erosion resistant coating 14 is greater than or equal to about 1000 kg/mm². In another embodiment, the hardness of the erosion resistant coating 14 is greater than or equal to about 2000 kg/mm². In yet another embodiment, the hardness of erosion resistant coating 14 is less than or equal to about 4000 kg/mm². In still another embodiment, the hardness of the erosion resistant coating 14 is less than or equal to about 3000 kg/mm².

The roughness average (Ra) of the erosion resistant coating 14, which is the arithmetic average of the absolute values of the measured profile height deviations in the erosion resistant coating 14 taken within the sampling length and measured from the graphical centerline, can be less than or equal to about 75 microinches. Within this range, the erosion resistant coating 14 can have a Ra of less than or equal to about 60 microinches. In one embodiment, the erosion resistant coating 14 has a Ra of less than or equal to about 50 microinches. In another embodiment, the erosion resistant coating 14 has a Ra of less than or equal to about 40 microinches. In yet another embodiment, the erosion resistant coating 14 has a Ra of greater than or equal to about 10 microinches. In still another embodiment, the erosion resistant coating 14 has a Ra of greater than or equal to about 20 microinches.

While there is no specific upper limit to the number of individual layers that may form the multilayer erosion resistant coating 14, there naturally must be at least two 2 layers. Within the multilayer erosion resistant coating 14, the thermal expansion and, by extension, the thermocyclic stress of the individual layers with the substrate 12 and between the individual layers should be considered. For example, the thermocyclic stress of the individual layers should not exceed the yield stress of the overall multilayer erosion resistant coating 14.

Furthermore, within the multilayer erosion resistant coating 14, each layer may have a different thickness and/or each layer may have a non-uniform thickness. The average thickness of each layer may independently be about 5 nanometers (nm) to about 25 micrometers (μm). Within this range, the average thickness of each layer can independently be greater than or equal to about 100 nm, specifically greater than or equal to about 1 μm. Also within this range, the average thickness of each layer can independently be less than or equal to 10 μm, specifically less than or equal to about 5 μm. The average thickness of the overall multilayer coating 14 may be about 1 μm to about 200 μm. Within this range, the average thickness of the overall multilayer coating 14 can be greater than or equal to about 5 μm, specifically greater than or equal to about 7 μm. Also within this range, the average thickness of the thickness of the overall multilayer coating 14 can be less than or equal to 50 μm, specifically less than or equal to about 30 μm.

In one embodiment, at least a portion of the multilayer erosion resistant coating 14 can be a periodic repetition of individual layers. For example, two different compositions can be alternatingly stacked to form 3 or more layers. In addition, 3 different compositions may be stacked in any number of permutations including, but not limited to, 1-2-3-1-2-3-, 1-2-3-2-1-, and the like. If these alternatingly stacked layers are sufficiently thin (e.g., less than or equal to about 100 nm), a heterostructure or superlattice is formed, which can have a significantly improved hardness and fracture resistance than a thicker, individual layer.

As stated above, the erosion resistant coating 14 can be deposited on the substrate 12 using electron beam physical vapor deposition (EB-PVD) or ion plasma cathodic arc deposition. Although it may be desirable, when the erosion resistant coating 14 is a multilayer coating, it is not necessary that each layer of the multilayer erosion resistant coating 14 be deposited using the same deposition technique.

An EB-PVD apparatus generally includes a vacuum chamber containing a cathode, a power supply, and a target anode assembly. The anode target assembly includes an anode target of the metal or metals of the desired coating composition and a target holder. When more than one metal is deposited, a single target comprising an alloy of the metals to be deposited can be vaporized, or multiple targets can be co-vaporized. The deposition chamber is first evacuated to a specific pressure. The anode target is bombarded with an electron beam produced by an electron source (e.g., a tungsten filament), which is connected to the power supply. Intense heating of the anode target by the electron beam causes the surface of the target to melt or sublime, allowing vaporized molecules of the metal to travel upwardly, and then deposit on the surfaces of the substrate 12, producing the desired erosion resistant coating 14 whose thickness will depend on the duration of the coating process and the vapor flux that condenses on the substrate. Introducing a controlled gas into the chamber results in the deposition of a composition that is a compound of the target and the introduced gas on the substrate 12. Within the deposition chamber, the substrate 12 can be moved to achieve a uniform coating on various surfaces of the substrate 12.

In contrast, a cathodic arc apparatus generally includes a vacuum chamber containing an anode, a power supply, and a cathode target assembly connected to the power supply. The cathode target assembly includes a cathode target of the metal or metals of the desired coating composition and a target holder. When more than one metal is deposited, a single target comprising an alloy of the metals to be deposited can be vaporized, or multiple targets can be co-vaporized. The deposition chamber is first evacuated to a specific pressure. An arc is then generated using an electronic trigger; and an external magnetic field both sustains the arc and guides the arc to the face of the cathode target generating an intense source of highly ionized plasma ideal for depositing the coating onto the substrate 12. A bias voltage is established between the cathode target and the substrate 12 to drive deposition of the erosion resistant coating 14. By introducing controlled gases to the ionized plasma cloud, a compound of the target and the introduced gas can be deposited on the substrate 12. Within the deposition chamber, the substrate 12 can be moved to achieve a uniform coating on various surfaces of the substrate 12.

If only a portion of the substrate 12 is to be coated with the erosion resistant coating 14, then a mask can be used to cover the portion of the substrate 12 to remain uncoated prior to insertion of the substrate 12 into the deposition chamber. Specific masking techniques, such as hard masking and soft masking, are known to those skilled in the art in view of this disclosure.

The specific deposition parameters used to form the erosion resistant coating 14 can be determined by those skilled in the art in view of this disclosure without undue experimentation. The choice of techniques will depend on the particular application, substrate 12, temperatures, costs, and the like. For example, using EB-PVD instead of cathodic arc deposition on a given substrate 12 results in a slightly smoother erosion resistant coating 14. In addition, with EB-PVD, there can be more versatility in the coating compositions that can be deposited; but greater compositional control, particularly with multinary or complex alloys, can be achieved using cathodic arc deposition. EB-PVD generally allows for faster deposition of the erosion resistant coating 14. However, the cost of equipment for cathodic arc deposition is significantly lower than that for EP-PVD. The deposition temperatures for both techniques are similar, however, the higher instantaneous temperature at the arc spot allows for the increased compositional control when depositing multinary or complex alloys using cathodic arc deposition.

Both EB-PVD and cathodic arc deposition can produce erosion resistant coatings 14 that have the same, or substantially the same, microstructure and/or roughness average as the substrate 12 onto which they are deposited. For example, with EB-PVD, the roughness average of the deposited erosion resistant coating 14 is within about 1 to about 10 percent of the roughness average of the substrate 12; and with ion plasma cathodic arc deposition, the roughness average of the deposited erosion resistant coating 14 is within about 1 to about 33 percent of the roughness average of the substrate 12. The smoothness/roughness of the uncoated turbine engine component can be controlled by machining the component to a desired contour and/or dimension. Thus, in an advantageous feature, highly smooth as-deposited erosion resistant coatings 14 can be produced on smooth turbine engine components, without needing a post-deposition processing step. In this manner, once the coating step has been complete, the coated article 10 is ready to be used or to undergo subsequent manufacturing processes.

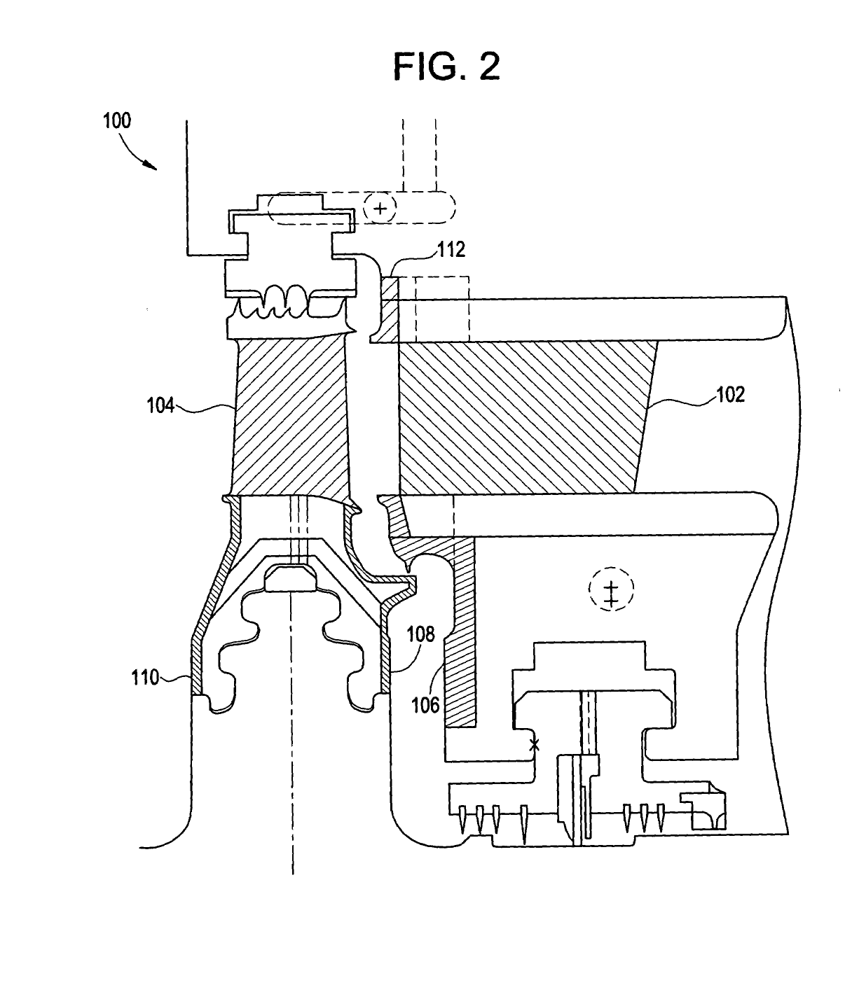

Referring now to FIG. 2, there is shown a cross section of a portion of turbine engine, generally designated 100, having various components coated with the erosion resistant coating 14, which are shaded in the figure. Specifically, the nozzle 102 and bucket 104 are two of the primary components that can be coated. Other areas of the turbine engine 100 that may be coated with the erosion resistant coatings 14 described herein include portions of the nozzle diaphragm (e.g., the root spill strip 106 and the diaphragm outer ring 112, which is also referred to as the tip spill strip), portions of the bucket dovetail (e.g., the spill strip platform 108 and other axial surfaces of the dovetail, which are generally designated 110), and any other area that may be susceptible to solid particle erosion. It should be noted that unlike with existing coating technologies, the coated areas shown in FIG. 2 do not require modification to the flow area to account for the thickness of the coatings.

Reference will now be made to the substrate being a turbine bucket 104. An exemplary multilayer erosion resistant coating 14 can be formed by depositing alternating layers of Ti and TiN onto the bucket 104.

For illustrative convenience, the multilayer erosion resistant coating 14 will be described by making reference again to FIG. 1. Specifically, as shown in the figure, the layers of TiN (18, 22, 26, and 30) are shaded, while the layers of Ti (16, 20, 24, and 28) are not shaded. It should be recognized that while reference has been made to 8 alternating layers (i.e., 16, 18, 20, 22, 24, 26, 28, and 30), this is only for illustrative purposes. One of ordinary skill in the art will appreciate that any number of alternating layers may be used. Furthermore, although the first alternating layer 16 (i.e., the layer closest to the turbine bucket) in this embodiment has been referred to as a Ti layer, it is possible for TiN to be used as the first alternating layer 16.

The alternating layers of Ti are deposited by either EB-PVD or cathodic arc deposition using a titanium ingot. When a layer of TiN is desired, nitrogen is introduced into the deposition chamber to nitride the metallic titanium vapor.

In a particularly advantageous feature of using alternating layers of Ti and TiN, the overall thickness of the coating can be quite high. The residual stress from deposition of TiN by itself is too great to allow for coatings thicker than about 5 μm to be formed. However, the cumulative thickness of the multilayer erosion resistant coating 14 can be about 5 μm to about 45 μm, with the individual layers of Ti and TiN each having a thickness of about 500 nm to about 5 μm.

Furthermore, the use of a soft and ductile material, such as a metal (which in this case is titanium), as a component of the multilayer erosion resistant coating 14 enables crack propagation to be minimized or prevented when a hard and brittle ceramic (which in this case is a nitride) layer is impacted by an erodent. This effectively extends the lifetime of the coating and, ultimately, the coated bucket.

The multilayer erosion resistant coating 14 of Ti/TiN and, ultimately, the coated bucket, is also resistant to oxidation up to about 1100 degrees Fahrenheit (° F.). Furthermore the multilayer erosion resistant coating 14 has a Ra of about 30 microinches to about 50 microinches and more specifically about 38 microinches to about 40 microinches. The hardness of the coated bucket is about 2000 kg/mm²to about 2600 kg/mm², and more specifically about 2400 kg/mm² to about 2600 kg/mm².

It has unexpectedly been found that the high cycle fatigue (HCF) properties of a substrate 12 (e.g., steel) were improved by coating the substrate 12 with the Ti/TiN multilayer erosion resistant coating 14 using EB-PVD or cathodic arc deposition. This is in stark contrast to the data obtained for such thermally sprayed coatings, wherein the HCF strength of the substrate were decreased.

In another exemplary embodiment, instead of a bucket 104, a nozzle 102 is coated with a multilayer erosion resistant coating 14. This multilayer erosion resistant coating 14 is formed by depositing alternating layers of TiAlN (18, 22, 26, and 30) and Ti (16, 20, 24, and 28). Once again, the 8 alternating layers (i.e., 16, 18, 20, 22, 24, 26, 28, and 30) are only for illustrative purposes, and any number of alternating layers may be used. Similarly, the first alternating layer 16 can either be a layer of TiAlN or Ti.

As described above, the alternating layers of Ti are deposited by either EB-PVD or cathodic arc deposition using a titanium ingot. However, when a layer of TiAlN is desired, either a single ingot of a TiAl alloy or two separate ingots (i.e., one of titanium and one of aluminum) can be used; and nitrogen is introduced into the deposition chamber to nitride the metallic titanium and aluminum vapors. The aluminum content in the TiAlN can be about 1 atomic percent to about 50 atomic percent. In an exemplary embodiment, the aluminum content is about 20 atomic percent to about 30 atomic percent. In a particularly exemplary embodiment, the aluminum content is about 26 atomic percent. An aluminum content above about 26 atomic percent provides increased oxidation resistance, but also diminished erosion resistance. At about 26 atomic percent Al, the TiAlN is oxidation resistant up to about 1380° F.

Like TiN, the residual stress from deposition of TiAlN by itself is too great to allow for coatings thicker than about 5 μm to be formed. However, the use of alternating layers of Ti and TiAlN allows for a cumulative thickness of about 5 μm to about 45 μm for the multilayer erosion resistant coating 14, with the individual layers of Ti and TiAlN having a thickness of about 500 nm to about 5 μm. In addition, the crack stopping benefits of using the soft and ductile titanium layers that are described above can also be observed for a Ti/TiAlN multilayer erosion resistant coating 14.

The multilayer erosion resistant coating 14 of Ti/TiAlN and, ultimately, the coated turbine nozzle, is resistant to oxidation up to about 1300° F. Furthermore the multilayer erosion resistant coating 14 has a Ra of about 40 microinches to about 50 microinches. The hardness of the coated nozzle is about 3000 kg/mm² to about 3600 kg/mm².

It should be recognized that the turbine engine components may comprise other coatings commonly deposited on turbine engine components, such as bond coats, thermal barrier coatings, lubricious coatings, and the like. If the erosion resistant coatings 14 described herein are to be deposited on an already coated turbine engine component, then the already coated turbine engine component is intended to be considered as the substrate 12 described above. Furthermore, in order to achieve a smooth coating, the already coated substrate 12 may be machined to have the desired smoothness prior to depositing the erosion resistant coating. Deposition of these other types of coatings are known by those skilled in the art.

In addition, the coated turbine engine component 10 can be subjected to other machining operations not intended to alter the surface characteristics of the erosion resistant coating 14. For example, the coated turbine engine component 10 can be welded or otherwise coupled to another component of the overall turbine engine during a post-deposition manufacturing step, as in the case of, for example, a coated nozzle. In this manner, rather than placing the entire nozzle assembly in the deposition chamber (and masking areas where a coating is not desired), smaller components of the turbine engine can be disposed in the deposition chamber and coated with the erosion resistant coating 14.

Furthermore, while not necessary to achieve a smooth coated article 10, the erosion resistant coating 14 can be machined to a specific contour and dimension after the erosion resistant coating 14 has been deposited onto the substrate 12.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

Also, the terms “first”, “second”, “bottom”, “top”, and the like do not denote any order, quantity, or importance, but rather are used to distinguish one element from another; and the terms “the”, “a”, and “an” do not denote a limitation of quantity, but rather denote the presence of at least one of the referenced items. The modifier “about” used in connection with a quantity is inclusive of the stated value and has the meaning dictated by the context or includes at least the degree of error associated with measurement of the particular quantity. Furthermore, all ranges reciting the same quantity or physical property are inclusive of the recited endpoints and independently combinable.

1. A coated turbine engine component, comprising:
a turbine engine component; and
an erosion resistant coating disposed on at least a portion of a surface of the turbine engine component using electron beam physical vapor deposition or ion plasma cathodic arc deposition.

2. The coated turbine engine component of claim 1, wherein the turbine engine component comprises a metal, an alloy, a superalloy, a ceramic, or a composite material.

3. The coated turbine engine component of claim 1, wherein the turbine engine component comprises a shroud, a bucket, a blade, a nozzle, a vane, a diaphragm component, a seal component, or a valve stem.

4. The coated turbine engine component of claim 1, wherein the erosion resistant coating comprises a ceramic, a cermet, or a combination comprising at least one of the foregoing.

5. The coated turbine engine component of claim 1, wherein the erosion resistant coating has a hardness of less than or equal to about 5000 kilograms per square millimeter.

6. The coated turbine engine component of claim 1, wherein the erosion resistant coating has a roughness average of less than or equal to about 75 microinches.

7. The coated turbine engine component of claim 1, wherein the coated turbine engine component has a high cycle fatigue strength that is greater than or equal to that of the turbine engine component without the erosion resistant coating disposed thereon.

8. The coated turbine engine component of claim 1, wherein the erosion resistant coating is a multilayer coating.

9. The coated turbine engine component of claim 8, wherein each layer of the multilayer erosion resistant coating has an average thickness of about 5 nanometers to about 25 micrometers.

10. The coated turbine engine component of claim 8, wherein the multilayer erosion resistant coating has an average total thickness of about 1 micrometer to about 200 micrometers.

11. The coated turbine engine component of claim 8, wherein the multilayer erosion resistant coating comprises alternating layers of a soft and ductile composition and a hard and brittle composition.

12. The coated turbine engine component of claim 11, wherein the soft and ductile composition is a metal and the hard and brittle composition is a ceramic.

13. The coated turbine engine component of claim 11, wherein the soft and ductile composition is titanium and the hard and brittle composition is a nitride.

14. A coated turbine engine component, comprising:
a turbine engine component; and
a multilayer erosion resistant coating having a roughness average of less than or equal to about 75 microinches disposed on at least a portion of a surface of the turbine engine component.

15. The coated turbine engine component of claim 14, wherein each layer of the multilayer erosion resistant coating is independently an electron beam physical vapor deposited layer or an ion plasma cathodic arc deposited layer.

16. The coated turbine engine component of claim 14, wherein each layer of the multilayer erosion resistant coating has an average thickness of about 5 nanometers to about 25 micrometers.

17. The coated turbine engine component of claim 14, wherein the multilayer erosion resistant coating has an average total thickness of about 1 micrometer to about 200 micrometers.

18. The coated turbine engine component of claim 14, wherein the coated turbine engine component has a high cycle fatigue strength that is greater than or equal to that of the turbine engine component without the erosion resistant coating disposed thereon.

19. The coated turbine engine component of claim 14, wherein the turbine engine component comprises a shroud, a bucket, a blade, a nozzle, a vane, diaphragm component, a seal component, or a valve stem.

20. The coated turbine engine component of claim 14, wherein the multilayer erosion resistant coating has a hardness of less than or equal to about 5000 kilograms per square millimeter.

21. The coated turbine engine component of claim 14, wherein the multilayer erosion resistant coating comprises alternating layers of a soft and ductile composition and a hard and brittle composition.

22. The coated turbine engine component of claim 21, wherein the soft and ductile composition is a metal and the hard and brittle composition is a ceramic.

23. The coated turbine engine component of claim 21, wherein the soft and ductile composition is titanium and the hard and brittle composition is a nitride.

24. A method, comprising:
disposing an erosion resistant coating on at least a portion of a surface of a turbine engine component by electron beam physical vapor deposition or ion plasma cathodic arc deposition.

25. The method of claim 24, wherein the erosion resistant coating is a multilayer erosion resistant coating, and wherein each layer of the multilayer erosion resistant coating is independently an electron beam physical vapor deposited layer or an ion plasma cathodic arc deposited layer.

26. The method of claim 24, wherein the roughness average of the disposed erosion resistant coating is within about 1 to about 33 percent of the roughness average of the turbine engine component.

27. A method, comprising:
disposing a multilayer erosion resistant coating having a roughness average of less than or equal to about 75 microinches on at least a portion of a surface of a turbine engine component by electron beam physical vapor deposition or ion plasma cathodic arc deposition.

28. The method of claim 27, wherein the roughness average of the disposed multilayer erosion resistant coating is within about 1 to about 33 percent of the roughness average of the turbine engine component.
